(19) United States
(12) Patent Application Publication
(10) Pub. No.: US 2023/0317534 A1
(43) Pub. Date: Oct. 5, 2023

(54) SEMICONDUCTOR DEVICE AND METHOD OF PRODUCING SEMICONDUCTOR DEVICE

(71) Applicant: SUMITOMO ELECTRIC INDUSTRIES, LTD., Osaka (JP)

(72) Inventor: Masaki TANIYAMA, Osaka (JP)

(21) Appl. No.: 18/020,456

(22) PCT Filed: Jul. 26, 2021
(86) PCT No.: PCT/JP2021/027572

§ 371 Date: Feb. 9, 2023

(30) Foreign Application Priority Data
Aug. 19, 2020 (JP) 2020-138402

(51) Int. Cl. H01L 23/29; H01L 25/07; H01L 23/049; H01L 23/31; H01L 23/373; H01L 21/48; H01L 21/56

(52) U.S. Cl. CPC H01L 23/293; H01L 25/072; H01L 23/049; H01L 23/3121; H01L 23/3735; H01L 21/4817; H01L 21/565

(57) ABSTRACT

A semiconductor device includes a substrate including a first main surface and having a circuit pattern, a semiconductor chip disposed on the circuit pattern, a frame body extending in a direction intersecting the first main surface and surrounding an outer periphery of the substrate, and a resin portion arranged in a space surrounded by the frame body and covering the substrate and the semiconductor chip. The resin portion includes a first region located on the semiconductor chip in contact with the semiconductor chip, and a second region located on a side of the first region opposite from the side where the semiconductor chip is located, the second region having a same volume as the first region and having a projection plane projected in a same shape as the first region as viewed in a thickness direction of the substrate. The amount of air bubbles contained in the resin portion arranged in the first region is smaller than the amount of air bubbles contained in the resin portion arranged in the second region.

### TECHNICAL FIELD

The present disclosure relates to a semiconductor device and a method of producing a semiconductor device.

The present application claims priority based on Japanese Patent Application No. 2020-138402 filed on Aug. 19, 2020, the entire contents of which are incorporated herein by reference.

### BACKGROUND ART

A semiconductor device having a semiconductor element mounted on an insulating substrate is known (see, e.g., Patent Literature 1). The semiconductor device disclosed in Patent Literature 1 includes an electrode joined on the insulating substrate, the semiconductor element mounted on an upper surface of the electrode, a flow control member, and an insulating resin.

### CITATION LIST

### Patent Literature

Patent Literature 1: Japanese Patent Application Laid-Open No. 2018-006569

### SUMMARY OF INVENTION

A semiconductor device according to the present disclosure includes: a substrate including a first main surface and having a circuit pattern; a semiconductor chip disposed on the circuit pattern; a frame body extending in a direction intersecting the first main surface and surrounding an outer periphery of the substrate; and a resin portion arranged in a space surrounded by the frame body and covering the substrate and the semiconductor chip. The resin portion includes a first region located on the semiconductor chip in contact with the semiconductor chip, and a second region located on a side of the first region opposite from a side on which the semiconductor chip is located, the second region having a same volume as the first region and having a projection plane projected in a same shape as the first region as viewed in a thickness direction of the substrate. The amount of air bubbles contained in the resin portion arranged in the first region is smaller than the amount of air bubbles contained in the resin portion arranged in the second region.

### BRIEF DESCRIPTION OF DRAWINGS

FIG. 1 is a schematic perspective view of a semiconductor device in Embodiment 1;

FIG. 2 is a schematic plan view of the semiconductor device shown in FIG. 1 as viewed in a thickness direction of a heat dissipation plate;

FIG. 3 is a schematic cross-sectional diagram showing, in enlarged view, a portion of the semiconductor device shown in FIG. 1;

FIG. 4 is a flowchart illustrating typical steps of a method of producing the semiconductor device shown in FIG. 1;

FIG. 5 is a schematic perspective view illustrating the state of injecting a resin in a first resin injecting step;

FIG. 6 is a schematic perspective view illustrating the state of injecting a resin in a second resin injecting step;

FIG. 7 is a schematic perspective diagram showing, in enlarged view, a region including semiconductor chips in a semiconductor device in Embodiment 2; and

FIG. 8 is a schematic plan view of a semiconductor chip and a first region as viewed in a thickness direction of a substrate.

### DESCRIPTION OF EMBODIMENTS

### Problems to be Solved by Present Disclosure

According to Patent Literature 1, the flow control member is disposed along an end of the upper surface of the electrode. The insulating resin is provided so as to cover a portion of the flow control member, a side face of the electrode, and a portion of the insulating substrate. However, such a configuration requires the step of disposing the flow control member and the step of applying the insulating resin, leading to degraded productivity. Further, interfaces where members with different coefficients of linear expansion come into contact with each other, such as an interface created between the silicone gel sealed in the chassis as a sealing medium and the insulating resin, increase in number, so delamination would easily occur at the interfaces. Then, air may enter into the delaminated portion, causing partial discharge to occur starting from the delaminated portion. As a result, the dielectric withstand voltage may decrease, which may lead to a breakage of the semiconductor element. That is, the reliability is reduced.

In view of the foregoing, one of the objects is to provide a semiconductor device which can be improved in productivity while being improved in reliability.

### Advantageous Effects of Present Disclosure

According to the semiconductor device described above, the productivity can be improved while the reliability is improved.

### Description of Embodiments of Present Disclosure

Firstly, embodiments of the present disclosure will be listed and described. A semiconductor device according to the present disclosure includes: a substrate including a first main surface and having a circuit pattern; a semiconductor chip disposed on the circuit pattern; a frame body extending in a direction intersecting the first main surface and surrounding an outer periphery of the substrate; and a resin portion arranged in a space surrounded by the frame body and covering the substrate and the semiconductor chip. The resin portion includes a first region located on the semiconductor chip in contact with the semiconductor chip, and a second region located on a side of the first region opposite from a side on which the semiconductor chip is located, the second region having a same volume as the first region and having a projection plane projected in a same shape as the first region as viewed in a thickness direction of the substrate. The amount of air bubbles contained in the resin portion arranged in the first region is smaller than the amount of air bubbles contained in the resin portion arranged in the second region.

According to the semiconductor device of the present disclosure, the amount of air bubbles contained in the resin portion arranged in the first region is smaller than the amount of air bubbles contained in the resin portion arranged in the second region, which is located on a side of the first region opposite from the side on which the semiconductor chip is located, which has the same volume as the first region, and which has a projection plane that is projected in the same shape as the first region as viewed in the thickness direction of the substrate. This can reduce a risk that a high voltage applied to the semiconductor chip causes partial discharge starting from a portion where an air bubble is located in the first region arranged on the semiconductor chip. It is thus possible to suppress the reduction in dielectric withstand voltage. Accordingly, the risk of breakage of the semiconductor chip can be reduced, leading to improved reliability. Further, in the second region containing the greater amount of air bubbles than the first region, the resin can be injected during the producing step without lowering the viscosity more than necessary. It is thus possible to improve the productivity. The second region is located on a side of the first region opposite from the side where the semiconductor chip is located, so the second region is farther from the semiconductor chip than the first region. This can reduce the effect to the reduction in dielectric withstand voltage attributable to the air bubbles contained in this region. According to the above, the semiconductor device described above can be improved in productivity while being improved in reliability.

The semiconductor device described above may further include a conductive member connected to the semiconductor chip in the first region. The first and second regions may each have a thickness that is not less than the height of the conductive member connected to the semiconductor chip and not more than 50% of an entire thickness of the resin portion. Since the thicknesses of the first and second regions are not less than the height of the conductive member connected to the semiconductor chip, the resin is contained in the first region in between the conductive member and the semiconductor chip. Partial discharge would likely occur particularly in the resin located in between the conductive member and the semiconductor chip, or, in the first region. Reducing the amount of air bubbles contained in the resin in the first region than in the resin in the second region can reduce the possibility of breakage due to the partial discharge as described above, so the productivity can be improved while the reliability can be improved. It should be noted that the thickness of the first region and that of the second region may be not less than the thickness of the semiconductor chip.

In the semiconductor device described above, the semiconductor chip may be a wide bandgap semiconductor chip. A wide bandgap semiconductor chip refers to a semiconductor chip that has a semiconductor layer composed of a material with a larger bandgap than silicon as an operating layer. The wide bandgap semiconductor chip has, as the operating layer, a semiconductor layer composed of silicon carbide, gallium nitride, or gallium oxide, for example. Such a wide bandgap semiconductor chip has a high dielectric breakdown voltage, leading to further improvement in reliability.

In the semiconductor device described above, a resin constituting the resin portion may be silicone gel, epoxy resin, or urethane resin. Such a resin has high insulating properties, leading to further improvement in reliability.

In the semiconductor device described above, the first region may have a projection plane that is projected in a same shape as the semiconductor chip as viewed in the thickness direction of the substrate. This can further suppress the occurrence of partial discharge in the region on the semiconductor chip. The reliability can thus be improved more reliably.

In the semiconductor device described above, the semiconductor chip and the first region may each have a rectangular shape. The semiconductor chip and the first region may have projection planes whose centers overlap each other. The projection plane of the first region may have one side whose length is not more than twice the length of one side of the projection plane of the semiconductor chip corresponding to the one side of the projection plane of the first region. This can suppress the occurrence of partial discharge in the region on the semiconductor chip and in a region surrounding that region. Accordingly, the reliability can be improved even more reliably.

A method of producing a semiconductor device of the present disclosure is a method of producing a semiconductor device that includes a substrate including a first main surface and having a circuit pattern, a semiconductor chip disposed on the circuit pattern, a frame body extending in a direction intersecting the first main surface and surrounding an outer periphery of the substrate, and a resin portion arranged in a space surrounded by the frame body and covering the substrate and the semiconductor chip. The semiconductor device producing method includes the steps of: arranging the frame body to surround the substrate; following the arranging step, injecting a resin constituting the resin portion into the space surrounded by the frame body at a first speed; and following the step of injecting the resin portion at the first speed, injecting the resin constituting the resin portion into the space surrounded by the frame body at a second speed faster than the first speed.

According to the semiconductor device producing method of the present disclosure, the resin is injected into the space surrounded by the frame body by spending relatively long time as the first speed, for example, to thereby suppress entrained air bubbles during the injecting step. This can reduce the amount of air bubbles in the first region which is arranged on the semiconductor chip in contact with the semiconductor chip. Next, the resin is injected into the second region which is located farther from the semiconductor chip than the first region. Here, the resin to be arranged in the second region located farther from the semiconductor chip than the first region is injected into the second region at the second speed faster than the first speed. This can reduce the production time and improve the productivity. At this time, because of the fast injection speed, the amount of air bubbles contained in the resin arranged in the second region may become greater than that in the resin arranged in the first region. However, the resin arranged in the second region functions as a barrier layer to prevent oxidation from the atmosphere and the like, so it is less likely that partial discharge occurs starting from the portion where an air bubble is contained in the resin arranged in the second region. As a result, according to such a semiconductor device producing method, it is possible to improve the productivity while improving the reliability. It should be noted that the step of injecting the resin at the first speed and the step of injecting the resin at the second speed may be performed at a constant temperature, e.g. a first temperature, or the temperature may be changed while the resin is being injected.

A method of producing a semiconductor device of the present disclosure is a method of producing a semiconductor device that includes a substrate including a first main surface and having a circuit pattern, a semiconductor chip disposed on the circuit pattern, a frame body extending in a direction intersecting the first main surface and surrounding an outer periphery of the substrate, and a resin portion arranged in a space surrounded by the frame body and covering the substrate and the semiconductor chip. The semiconductor device producing method includes the steps of: arranging the frame body to surround the substrate; following the arranging step, injecting a resin constituting the resin portion, being at a first temperature, into the space surrounded by the frame body; and following the step of injecting the resin portion at the first temperature, injecting the resin constituting the resin portion, being at a second temperature lower than the first temperature, into the space surrounded by the frame body.

According to the semiconductor device producing method of the present disclosure, the resin is injected into the space surrounded by the frame body in the state of low viscosity as the first temperature, for example, so that even if air bubbles are entrained during the injecting step, the air bubbles will easily rise in the resin to reach the surface of the resin. This can reduce the amount of air bubbles in the first region which is arranged on the semiconductor chip in contact with the semiconductor chip. Next, the resin is injected into the space surrounded by the frame body in the state of high viscosity as the second temperature lower than the first temperature. At this time, the resin in the second region, located on a side of the first region opposite from the side on which the semiconductor chip is located and having the same volume as the first region and having a projection plane projected in the same shape as the first region as viewed in the thickness direction of the substrate, is capable of cooling the resin in the first region injected at the first temperature. This can suppress the shortening of the pot life of the resin. Here, for the resin arranged in the second region, which is located farther from the semiconductor chip than the first region, air entrained in the resin during the injection cannot be fully released due to its relatively high viscosity, so the amount of air bubbles contained therein may be greater than that in the resin arranged in the first region. However, the resin arranged in the second region functions as a barrier layer to prevent oxidation from the atmosphere and the like, so partial discharge starting from the portion of an air bubble contained in the resin arranged in the second region is less likely to occur. Further, raising of the resin temperature can be simplified when the resin is injected at the second temperature. As a result, according to such a semiconductor device producing method, it is possible to improve the productivity while improving the reliability.

### Details of Embodiments of Present Disclosure

Embodiments of the semiconductor device of the present disclosure will be described below with reference to the drawings. In the drawings referenced below, the same or corresponding portions are denoted by the same reference numerals and the description thereof will not be repeated.

### Embodiment 1

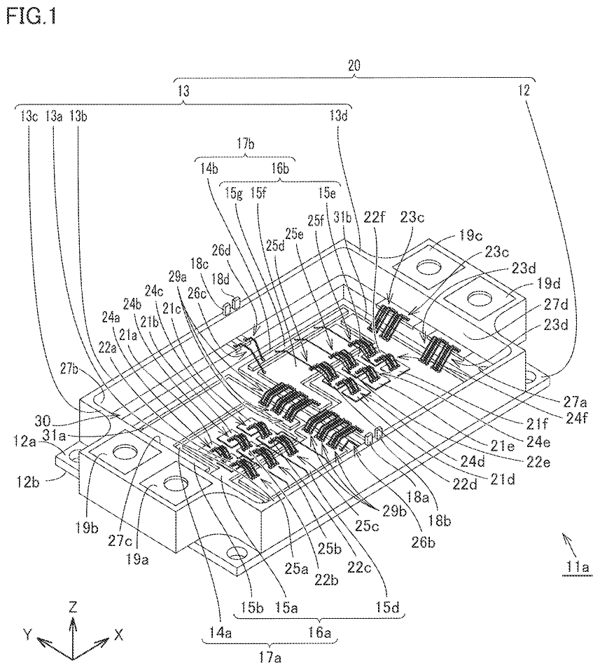

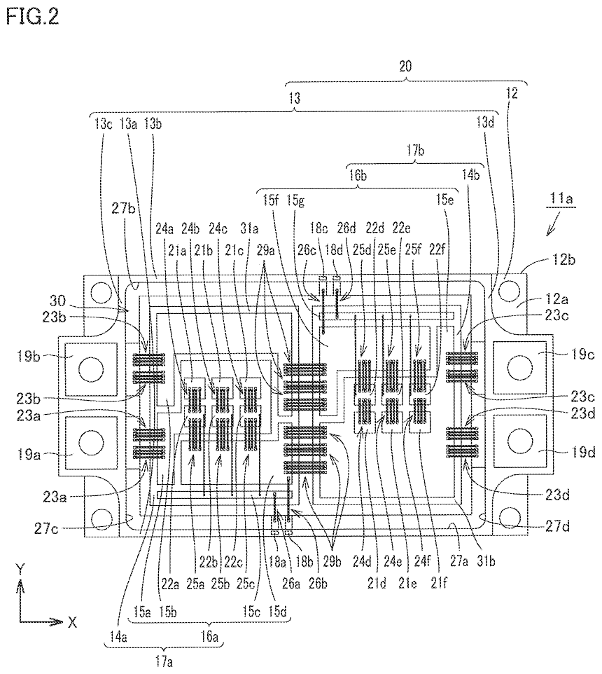

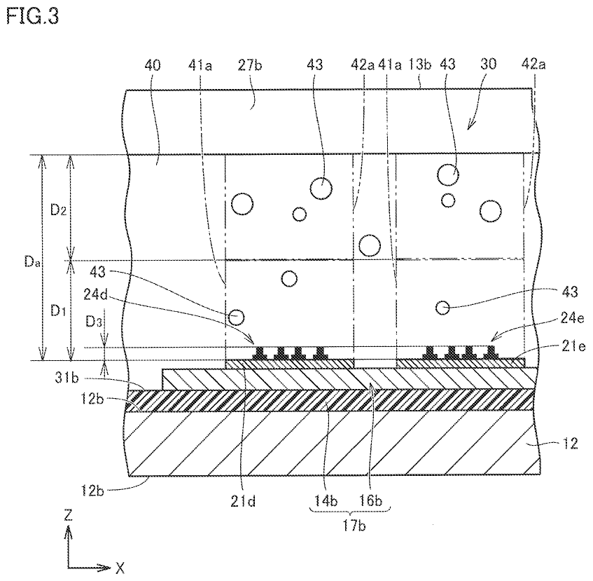

A configuration of a semiconductor device in Embodiment 1 of the present disclosure will now be described. FIG. 1 is a schematic perspective view of a semiconductor device in Embodiment 1. FIG. 2 is a schematic plan view of the semiconductor device shown in FIG. 1 as viewed in a thickness direction of a heat dissipation plate. FIG. 2 is a schematic perspective view of the semiconductor device shown in FIG. 1. FIG. 3 is a schematic cross-sectional diagram showing, in enlarged view, a portion of the semiconductor device shown in FIG. 1. FIG. 3 is a cross-sectional view taken in a plane containing semiconductor chips and parallel to the X-Z plane. In FIGS. 1 and 2, a resin portion included in the semiconductor device is not illustrated. Further, in FIG. 3, first regions 41a, described later, are indicated by long dashed short dashed lines, and second regions 42a, described later, are indicated by long dashed double-short dashed lines. It should be noted that in FIG. 3, for ease of understanding, the hatching for the resin portion is omitted and wires, described later, extending in the Y direction are illustrated.

Referring to FIGS. 1, 2, and 3, a semiconductor device 11a in Embodiment 1 includes a heat dissipation plate 12, a frame body 13 disposed on the heat dissipation plate 12, substrates 17a and 17b disposed on the heat dissipation plate 12, plate-shaped electrodes (busbars) 19a, 19b, 19c, and 19d, terminals 18a, 18b, 18c, and 18d, semiconductor chips 21a, 21b, 21c, 21d, 21e, 21f, 22a, 22b, 22c, 22d, 22e, and 22f, and a resin portion 40. The heat dissipation plate 12 and the frame body 13 constitute a case 20 provided for the semiconductor device 11a.

The heat dissipation plate 12 is made of metal. The heat dissipation plate 12 is made of copper, for example. The heat dissipation plate 12 may have a surface plated with nickel or the like. The heat dissipation plate 12 has a rectangular outer shape with long sides extending in an X direction and short sides extending in a Y direction as viewed in its thickness direction. The substrate 17a is joined on one main surface 12a of the heat dissipation plate 12 by solder or the like, which is not shown in the figure. On another main surface 12b of the heat dissipation plate 12, a heat dissipation fin (not shown) for efficient heat dissipation or the like, for example, may be attached. The thickness direction of the heat dissipation plate 12 and of the substrate 17a is a Z direction.

The substrate 17a has an insulating plate 14a having insulating properties and a circuit pattern 16a having electrical conductivity. The substrate 17a has a first main surface 31a. The first main surface 31a is a main surface located opposite from the heat dissipation plate 12 in the thickness direction of the insulating plate 14a. The circuit pattern 16a is disposed on the insulating plate 14a. The substrate 17a is configured by stacking the circuit pattern 16a on the insulating plate 14a. The circuit pattern 16a is composed of a plurality of circuit boards. In the present embodiment, the circuit pattern 16a includes a first circuit board 15a, a second circuit board 15b, a third circuit board 15c, and a fourth circuit board 15d. In the present embodiment, the circuit pattern 16a is copper wiring. Similar to the substrate 17a, the substrate 17b has an insulating plate 14b having insulating properties and a circuit pattern 16b which is copper wiring. The substrate 17b has a first main surface 31b. The circuit pattern 16b includes a fifth circuit board 15e, a sixth circuit board 15f, and a seventh circuit board 15g.

The semiconductor chips 21a, 21b, 21c, 22a, 22b, and 22c are disposed on the first circuit board 15a. The semiconductor chips 21d, 21e, 21f, 22d, 22e, and 22f are disposed on the fifth circuit board 15e. The semiconductor chips 21a, 21b, 21c, 21d, 21e, 21f, 22a, 22b, 22c, 22d, 22e, and 22f are wide bandgap semiconductor chips. A wide bandgap semiconductor chip refers to a semiconductor chip that has, as an operating layer, a semiconductor layer composed of a material with a larger bandgap than silicon. For example, a wide bandgap semiconductor chip has a semiconductor layer composed of silicon carbide, gallium nitride, or gallium oxide as the operating layer. Specifically, the semiconductor chips 21a-21f and 22a-22f have a semiconductor layer composed of silicon carbide as the operating layer. Such wide bandgap semiconductor chips have a high dielectric breakdown voltage, leading to further improvement in reliability. The wide bandgap semiconductor chips also have high thermal resistance, so they can achieve semiconductor devices (power modules) that can be used in environments exceeding 175° C., for example. For use in such a high temperature environment, the resin constituting a resin portion 40, which will be described later, is required to have a high glass transition point. Resins with a higher glass transition point inevitably have a higher curing temperature. The higher the curing temperature, the longer it takes to cool and remove the resin after curing. Therefore, for semiconductor devices using wide bandgap semiconductor chips, there is a particular need to improve productivity, such as shortening of the production time during manufacture. The semiconductor chips 21a, 21b, 21c, 21d, 21e, and 21f are Schottky barrier diodes (SBDs), for example. The semiconductor chips 22a, 22b, 22c, 22d, 22e, and 22f are metal-oxide-semiconductor field effect transistors (MOSFETs), for example. It should be noted that the semiconductor chips 21a, 21b, 21c, 22a, 22b, and 22c are rectangular as viewed in the thickness direction of the substrates 17a, 17b.

The frame body 13 is attached to the heat dissipation plate 12 so as to extend from the one main surface 12a of the heat dissipation plate 12 and surround the substrates 17a and 17b as viewed in the thickness direction of the substrates 17a and 17b. In the present embodiment, the frame body 13 is formed to rise from the one main surface 12a of the heat dissipation plate 12. The frame body 13 is fixed to the heat dissipation plate 12 by an adhesive, for example. The frame body 13 is made, for example, of a resin having insulating properties. The frame body 13 includes a first wall portion 13a, a second wall portion 13b, a third wall portion 13c, and a fourth wall portion 13d. The first wall portion 13a and the second wall portion 13b are arranged to face each other in a direction (Y direction) corresponding to the short sides of the heat dissipation plate 12 as viewed in the thickness direction of the heat dissipation plate 12. The third wall portion 13c and the fourth wall portion 13d are arranged to face each other in a direction (X direction) corresponding to the long sides of the heat dissipation plate 12 as viewed in the thickness direction of the heat dissipation plate 12. The frame body 13 has inner wall surfaces 27a, 27b, 27c, and 27d forming a rectangle as viewed in the thickness direction of the heat dissipation plate 12. Specifically, the frame body 13 has the inner wall surface 27a, the inner wall surface 27b facing the inner wall surface 27a, the inner wall surface 27c connected to the inner wall surface 27a and the inner wall surface 27b, and the inner wall surface 27d connected to the inner wall surface 27a and the inner wall surface 27b and facing the inner wall surface 27c. The frame body 13 rises in a direction intersecting the first main surfaces 31a and 31b. Specifically, the inner wall surfaces 27a, 27b, 27c, and 27d rise perpendicular to the first main surfaces 31a and 31b.

The resin portion 40 is arranged in a space 30 surrounded by the frame body 13. The resin portion 40 covers the substrates 17a and 17b and the semiconductor chips 21a-21f and 22a-22f In the present embodiment, the resin constituting the resin portion 40 is an epoxy resin. In the present embodiment, one type of resin constitutes the resin portion 40.

The electrodes 19a, 19b, 19c, and 19d are each plate-shaped and made of metal. The electrodes 19a and 19b are attached to the third wall portion 13c. The electrodes 19c and 19d are attached to the fourth wall portion 13d. The electrodes 19a, 19b, 19c, and 19d each have a bent strip shape. In the present embodiment, the electrodes 19a, 19b, 19c, and 19d are each formed by, for example, bending a strip-shaped copper plate. The semiconductor device 11a secures electrical connection with the outside by means of the electrodes 19a, 19b, 19c, and 19d. It should be noted that the terminals 18a, 18b, 18c, and 18d are also provided to secure electrical connection with the outside. The terminals 18a and 18b are attached to the fourth wall portion 13d. The terminals 18c and 18d are attached to the third wall portion 13c.

The electrode 19a and the first circuit board 15a are connected by wire 23a. The electrode 19b and the second circuit board 15b are connected by wire 23b. The electrode 19c and the fifth circuit board 15e are connected by wire 23c. The electrode 19d and the fifth circuit board 15e are connected by wire 23d. The semiconductor chip 21a and the semiconductor chip 22a are connected by wire 24a. The semiconductor chip 21b and the semiconductor chip 22b are connected by wire 24b. The semiconductor chip 21c and the semiconductor chip 22c are connected by wire 24c. The semiconductor chip 21d and the semiconductor chip 22d are connected by wire 24d. The semiconductor chip 21e and the semiconductor chip 22e are connected by wire 24e. The semiconductor chip 21f and the semiconductor chip 22f are connected by wire 24f The semiconductor chip 22a and the fourth circuit board 15d are connected by wire 25a. The semiconductor chip 22b and the fourth circuit board 15d are connected by wire 25b. The semiconductor chip 22c and the fourth circuit board 15d are connected by wire 25c. The semiconductor chip 22d and the sixth circuit board 15f are connected by wire 25d. The semiconductor chip 22e and the sixth circuit board 15f are connected by wire 25e. The semiconductor chip 22f and the sixth circuit board 15f are connected by wire 25f. The wires 24a-24f and 25a-25f as the conductive members are connected to the semiconductor chips 21a-21f and 22a-22f within first regions 41a, which will be described later. It should be noted that the wires 24a and the like may each be connected by wire bonding. Alternatively, the wires 24a and the like may each be connected by stitch bonding.

The second circuit board 15b and the sixth circuit board 15f are connected by wire 29a. The fourth circuit board 15d and the fifth circuit board 15e are connected by wire 29b. The terminal 18a and the third circuit board 15c are connected by wire 26a. The terminal 18b and the fourth circuit board 15d are connected by wire 26b. The terminal 18c and the sixth circuit board 15f are connected by wire 26c. The terminal 18d and the seventh circuit board 15g are connected by wire 26d. Further, the semiconductor chips 22a, 22b, and 22c are each connected to the third circuit board 15c by wire, and the semiconductor chips 22d, 22e, and 22f are each connected to the seventh circuit board 15g by wire. For the wires, thick aluminum wire may be adopted, or ribbon wire may be adopted.

Here, the resin portion 40 includes first regions 41a that are located on the semiconductor chips 21a, 21b, 21c, 21d, 21e, 21f, 22a, 22b, 22c, 22d, 22e, and 22f, and second regions 42a that are located on a side of the first regions 41a opposite from the side where the semiconductor chips 21a, 21b, 21c, 21d, 21e, 21f, 22a, 22b, 22c, 22d, 22e, and 22f are located, the second regions 42a having the same volume as the first regions 41a and having projection planes projected in the same shape as the first regions 41a as viewed in the thickness direction of the substrate 17b (particularly see FIG. 3). Specifically, the first regions 41a are arranged on the semiconductor chips 21a, 21b, 21c, 21d, 21e, 21f, 22a, 22b, 22c, 22d, 22e, and 22f In the present embodiment, of the resin portion 40 covering the circuit pattern 16a and the insulating plate 14a, the regions on the semiconductor chips 21a, 21b, 21c, 21d, 21e, 21f, 22a, 22b, 22c, 22d, 22e, and 22f are the first regions 41a. In other words, as viewed in the thickness direction of the substrates 17a, 17b, the first regions 41a have projection planes that are projected in the same shapes as the semiconductor chips 21a, 21b, 21c, 21d, 21e, 21f, 22a, 22b, 22c, 22d, 22e, and 22f, respectively. In the present embodiment, the second regions 42a are arranged on an upper side of the first regions 41a in the state where the substrate 17a is arranged on the lower side in the Z direction.

Specifically, the second regions 42a are arranged on the first regions 41a. In the present embodiment, both of the first regions 41a and the second regions 42a are of a rectangular parallelepiped shape. The first regions 41a and the second regions 42a are identical in volume. The projection planes of the first regions 41a and the projection planes of the second regions 42a are planes respectively facing the semiconductor chips 21a, 21b, 21c, 21d, 21e, 21f, 22a, 22b, 22c, 22d, 22e, and 22f, for example. As viewed in the thickness direction of the substrates 17a, 17b, the projection planes of the first regions 41a and the projection planes of the second regions 42a are identical in shape. The first regions 41a have a thickness D₁ and the second regions 42a have a thickness D₂, which are each not less than a height D₃ of the wires 24a-24f and 25a-25f, being the conductive members connected to the semiconductor chips 21a-21f and 22a-22f, and not more than 50% of an entire thickness D₃ of the resin portion 40. It should be noted that the first regions 41a and the second regions 42a each have the thickness direction identical to that of the substrate 17a. As used herein, the entire thickness Da of the resin portion 40 is a distance from the upper surfaces of the semiconductor chips 21a-21f and 22a-22f to the upper surface of the resin. Further, the height D₃ is a height from the upper surfaces of the semiconductor chips 21a-21f and 22a-22f to the wires 24a-24f and 25a-25f as the conductive members. In the present embodiment, the thickness D₁ of the first regions 41a and the thickness D₂ of the second regions 42a are each 50% of the entire thickness Dₐ of the resin portion 40. In the present embodiment, the thickness Dₐ of the resin portion 40 is 12 mm, for example. The thickness D₁ of the first regions 41a and the thickness D₂ of the second regions 42a are each 6 mm, for example. It should be noted that the height D₃ of the wires 24a-24f and 25a-25f is chosen to be 1 to 2 mm, for example. When copper plates (copper clips) are used as the conductive members, the height of the conductive members is chosen to be 0.3 to 1 mm, for example.

Here, the amount of air bubbles 43 contained in the resin portion 40 arranged in the first regions 41a is smaller than the amount of air bubbles 43 contained in the resin portion 40 arranged in the second regions 42a. The measurement of the amount of air bubbles 43 is conducted as follows. In this case, the measurement is conducted using ultrasonic testing (scanning acoustic tomograph (SAT) observation). The amount of air bubbles 43 is specified by the void fraction, i.e., the volume percentage of voids per unit volume.

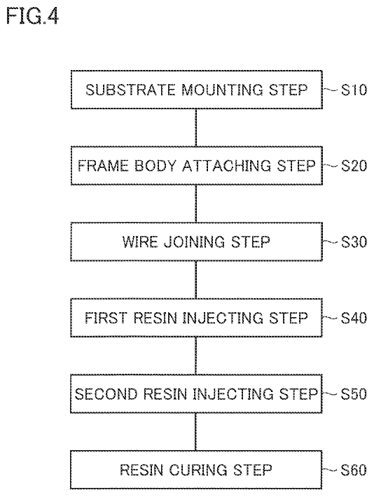

A method of producing the semiconductor device 11a will now be described in brief. FIG. 4 is a flowchart illustrating typical steps in the method of producing the semiconductor device shown in FIG. 1. Referring to FIG. 4, in the method of producing the semiconductor device 11a in Embodiment 1, a substrate mounting step is first performed as a step S10. In this step S10, the substrates 17a and 17b, with the semiconductor chips 21a-21f and 22a-22f attached to the circuit patterns 16a and 16b of the insulating plates 14a and 14b, are mounted on the heat dissipation plate 12. In this case, the substrates 17a and 17b are joined onto the heat dissipation plate 12 by solder or the like. Next, a frame body attaching step is performed as a step S20. In this step S20, the frame body 13 is attached onto the heat dissipation plate 12 with an adhesive or the like, so as to surround the substrates 17a and 17b. Subsequently, a wire joining step is performed as a step S30 to electrically connect the members. In this step S30, wire bonding or the like is used to join the electrode 19a and the first circuit board 15a by the wire 23a, to thereby electrically connect the electrode 19a and the first circuit board 15a. The other members are also joined by the wires 23b and the like.

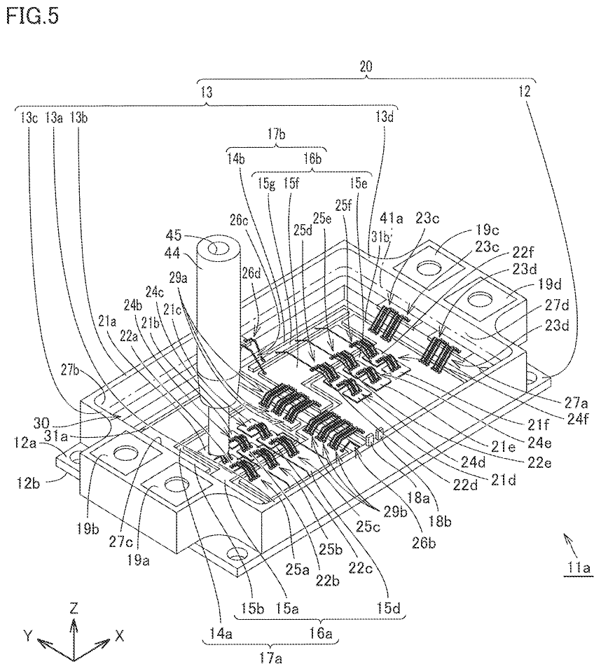

Next, a first resin injecting step is performed as a step S40. Here, an epoxy resin with a curing temperature of 120° C. is used. Specifically, a two part epoxy resin, for example, can be used. FIG. 5 is a schematic perspective view illustrating the state of injecting the resin in the first resin injecting step. Referring to FIG. 5, an uncured epoxy resin is prepared, and using a hole 45 formed in a discharge portion 44, the epoxy resin is injected at a first speed through the hole 45 into the space 30 surrounded by the frame body 13. At this time, the temperature of the epoxy resin is 80° C. as the first temperature. The epoxy resin is injected so as to achieve a final thickness D₁ of 5.5 mm in the first regions 41a. At this time, the injected epoxy resin flows horizontally over the substrates 17a and 17b (spreading along the X-Y plane) and accumulates on the substrates 17a and 17b. Here, by injecting the resin into the space 30 surrounded by the frame body 13 over a relatively large amount of time (slowly) as the first speed, entering of air bubbles 43 during the injection can be suppressed. The epoxy resin is relatively high in temperature, at 80° C., and low in viscosity. Therefore, even if air bubbles 43 are entrained during the injection, the air bubbles 43 will easily rise in the resin to reach the surface of the resin. Therefore, the amount of air bubbles contained in the first regions 41a can be reduced.

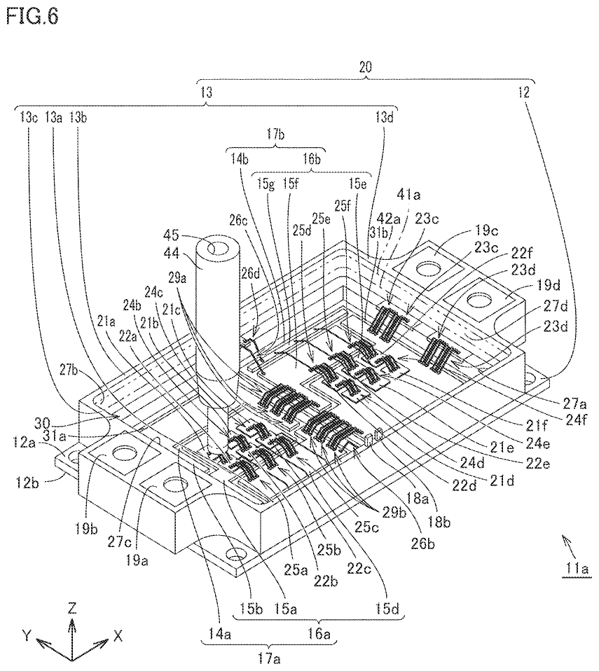

Thereafter, a second resin injecting step is performed as a step S50. FIG. 6 is a schematic perspective view illustrating the state of injecting the resin in the second resin injecting step. Referring to FIG. 6, in the present embodiment, the same type of epoxy resin as in the first resin injecting step is used. The epoxy resin maintained at the first temperature is continuously injected through the hole 45 into the space 30 surrounded by the frame body 13, at a second speed faster than the first speed. At this time, the injected epoxy resin flows horizontally over the first regions 41a and accumulates on the first regions 41a. The epoxy resin is injected so as to achieve a final thickness D₂ of 6 mm in the second regions 42a.

Next, a resin curing step is performed as a step S60. The resin curing step is carried out in two stages. Following the completion of the second resin injecting step, the temperature is raised and, with the temperature maintained at 90° C., the first stage of curing, primary cure, is conducted with a curing time of two hours. Thereafter, the temperature is raised and, with the temperature maintained at 150° C., the second stage of curing, secondary cure, is conducted with a curing time of three hours. By using the epoxy resin and curing it in two stages in this manner, the inner layer of the resin portion 40 can be sufficiently cured. After the curing is completed, the semiconductor device 11a in Embodiment 1 is obtained.

According to the semiconductor device 11a as described above, the amount of air bubbles 43 contained in the resin portion 40 arranged in the first regions 41a, 41b is smaller than the amount of air bubbles 43 contained in the resin portion 40 arranged in the second regions 42a which are located on a side of the first regions 41a opposite from the side on which the semiconductor chips 21a-21f and 22a-22f are located and which have the same volume as the first regions 41a and have projection planes projected in the same shape as the first regions 41a as viewed in the thickness direction of the substrates 17a, 17b. This can reduce the risk that a high voltage applied to the semiconductor chips 21a-21f and 22a-22f causes partial discharge starting from a portion where an air bubble 43 is located in any of the first regions 41a arranged on the semiconductor chips 21a-21f and 22a-22f It is thus possible to suppress the reduction in dielectric withstand voltage. Accordingly, the risk of breakage of the semiconductor chips 21a-21f and 22a-22f can be reduced, and the reliability can be improved. Further, in the second regions 42a containing the greater amount of air bubbles 43 than the first regions 41a, the resin can be injected during the production step without lowering the viscosity more than necessary. It is thus possible to improve the productivity. The second regions 42a are located on a side of the first regions 41a opposite from the side where the semiconductor chips 21a-21f and 22a-22f are located, so the second regions 42a are farther from the semiconductor chips than the first regions 41a. This can reduce the effect to the reduction in dielectric withstand voltage attributable to the air bubbles 43 contained in the second regions 42a. According to the above, the semiconductor device 11a described above can be improved in productivity while being improved in reliability. Although the resin is maintained at the same temperature during the steps of injecting the resin at the first speed and at the second speed in the above embodiment, not limited thereto, the resin can be injected at different temperatures.

In the semiconductor device 11a described above, as viewed in the thickness direction of the substrate 17b, the first regions 41a have projection planes projected in the same shapes as the semiconductor chips 21a, 21b, 21c, 21d, 21e, 21f, 22a, 22b, 22c, 22d, 22e, and 22f This can further suppress the occurrence of partial discharge in the regions on the semiconductor chips 21a, 21b, 21c, 21d, 21e, 21f, 22a, 22b, 22c, 22d, 22e, and 22f Accordingly, such a semiconductor device 11a is a semiconductor device that can be more reliably improved in reliability.

In the present embodiment, only one type of resin constitutes the resin portion 40. There is no interface where different resins come into contact with each other. Therefore, delamination starting from such a portion will not occur, leading to further improvement in reliability.

In the semiconductor device 11a described above, the semiconductor chips 21a-21f and 22a-22f are wide bandgap semiconductor chips having a semiconductor layer composed of silicon carbide as an operating layer. Such semiconductor chips 21a-21f and 22a-22f have a high dielectric breakdown voltage, which can further improve the reliability. In addition, even if a resin with a high glass transition point is used, the overall resin injection speed can be accelerated. Therefore, the production time can be reduced, resulting in improved productivity.

In the present embodiment, the thickness D₁ of the first regions 41a and the thickness D₂ of the second regions 42a are not less than the height D₃ of the wires 24a-24f and 25a-25f connected to the semiconductor chips 21a-21f and 22a-22f, and not more than 50% of the entire thickness Dₐ of the resin portion 40. Since the thickness D₁ of the first regions 41a and the thickness D₂ of the second regions 42a are not less than the height D₃ of the wires 24a-24f and 25a-25f which are the conductive members connected to the semiconductor chips 21a-21f and 22a-22f, there is the resin in the first regions 41a in between the wires 24a-24f and 25a-25f as the conductive members and the semiconductor chips 21a-21f and 22a-22f. Particularly prone to partial discharge is the resin in the first regions 41a, located between the wires 24a-24f and 25a-25f and the semiconductor chips 21a-21f and 22a-22f Reducing the amount of air bubbles contained in the resin in the first regions 41a than in the resin in the second regions 42a makes breakage due to the partial discharge described above less likely to occur, so the productivity can be improved while the reliability can be improved. It should be noted that making the thickness D₂ of the second regions 42a thicker, for example making the thickness D₂ of the second regions 42a thicker than the thickness D₁ of the first regions 41a, can accelerate the overall resin injection speed. Therefore, the production time can be shortened, leading to further improvement in productivity.

Further, according to the method of producing the semiconductor device 11a as described above, the resin is injected into the space 30 surrounded by the frame body 13 by spending relatively long time as the first speed, for example, to thereby suppress entrained air bubbles 43 during the injecting step. This can reduce the amount of air bubbles 43 in the first regions 41a which are arranged on the semiconductor chips 21a-21f and 22a-22f in contact with the semiconductor chips 21a-21f and 22a-22f Next, the resin is injected into the second regions 42a which are located farther from the semiconductor chips 21a-21f and 22a-22f than the first regions 41a. Here, the resin to be arranged in the second regions 42a, which are farther from the semiconductor chips 21a-21f and 22a-22f than the first regions 41a, is injected into the second regions 42a at the second speed faster than the first speed. This can reduce the production time and improve the productivity. At this time, because of the fast injection speed, the amount of air bubbles 43 contained in the resin arranged in the second regions 42a may become greater than that in the resin arranged in the first regions 41a. However, the resin arranged in the second regions 42a functions as a barrier layer to prevent oxidation from the atmosphere and the like, so it is less likely that partial discharge occurs starting from the portion where an air bubble 43 is contained in the resin arranged in any of the second regions 42a. As a result, according to such a method of producing the semiconductor device 11a, it is possible to improve the productivity while improving the reliability.

It should be noted that the method of producing the semiconductor device 11a may be as follows. The method of producing the semiconductor device 11a is a method of producing the semiconductor device 11a which includes: substrates 17a and 17b including first main surfaces 31a and 31b and having circuit patterns 16a and 16b; semiconductor chips 21a-21f and 22a-22f disposed on the circuit patterns 16a and 16b; a frame body 13 extending in a direction intersecting the first main surfaces 31a and 31b and surrounding outer peripheries of the substrates 17a and 17b; and a resin portion 40 arranged in a space 30 surrounded by the frame body 13 and covering the substrates 17a and 17b and the semiconductor chips 21a-21f and 22a-22f The method of producing the semiconductor device 11a includes the steps of: arranging the frame body 13 to surround the substrates 17a and 17b; following the arranging step, injecting a resin constituting the resin portion 40, being at a first temperature, into the space 30 surrounded by the frame body 13; and following the step of injecting the resin at the first temperature, injecting the resin constituting the resin portion 40, being at a second temperature lower than the first temperature, into the space 30 surrounded by the frame body 13. Specifically, for example, the temperature of the resin is 80° C. in the first resin injecting step, and the temperature of the resin is 50° C. in the second resin injecting step. The resin injecting speed in the first resin injecting step is the same as the resin injecting speed in the second resin injecting step.

According to such a method of producing the semiconductor device 11a, the resin is injected into the space 30 surrounded by the frame body 13 in the state of low viscosity as the first temperature, for example, so that even if air bubbles 43 are entrained during the injecting step, the air bubbles 43 will easily rise in the resin to reach the surface of the resin. This can reduce the amount of air bubbles 43 in the first regions 41a which are arranged on the semiconductor chips 21a-21f and 22a-22f in contact with the semiconductor chips 21a-21f and 22a-22f Next, the resin is injected into the space 30 surrounded by the frame body 13 in the state of high viscosity as the second temperature lower than the first temperature. At this time, the resin in the second regions 42a, located on a side of the first regions 41a opposite from the side on which the semiconductor chips 21a-21f and 22a-22f are located and having the same volume as the first regions 41a and having projection planes projected in the same shape as the first regions 41a as viewed in the thickness direction of the substrate 17a, is capable of cooling the resin in the first regions 41a injected at the first temperature. This can suppress the shortening of the pot life of the resin. Here, for the resin arranged in the second regions 42a located farther from the semiconductor chips 21a-21f and 22a-22f than the first regions 41a, air entrained in the resin during the injection cannot be fully released due to its relatively high viscosity, so the amount of air bubbles 43 contained therein may be larger than that in the resin arranged in the first regions 41a. However, the resin arranged in the second regions 42a functions as a barrier layer to prevent oxidation from the atmosphere and the like, so partial discharge starting from the portion of an air bubble 43 contained in the resin arranged in any of the second regions 42a is less likely to occur. Further, raising of the resin temperature can be simplified when the resin is injected at the second temperature. As a result, such a method of producing the semiconductor device 11a can improve the productivity while improving the reliability.

It should be noted that in the method of producing the semiconductor device 11a, the resin may be injected by changing the temperature and speed in the first and second resin injecting steps. In other words, the method of producing the semiconductor device 11a may include the steps of: arranging the frame body 13 to surround the substrates 17a and 17b; following the arranging step, injecting the resin constituting the resin portion 40, being at a first temperature, into the space 30 surrounded by the frame body 13 at a first speed; and following the step of injecting the resin at the first temperature and at the first speed, injecting the resin constituting the resin portion 40, being at a second temperature lower than the first temperature, into the space 30 surrounded by the frame body 13 at a second speed faster than the first speed. With such a method of producing the semiconductor device 11a as well, the productivity can be improved while the reliability is improved.

### Embodiment 2

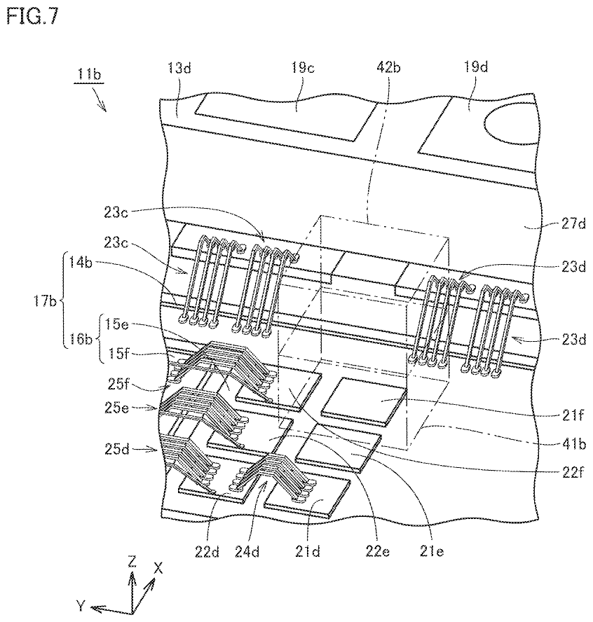

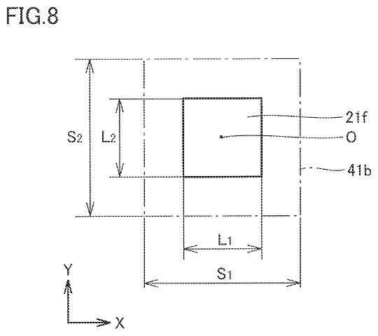

Another embodiment, Embodiment 2, will now be described. FIG. 7 is a schematic perspective diagram showing, in enlarged view, a region including a semiconductor chip 21f in a semiconductor device 11b in Embodiment 2. In FIG. 7, a first region 41b is indicated by long dashed short dashed lines, and a second region 42b is indicated by long dashed double-short dashed lines. FIG. 8 is a schematic plan view of the semiconductor chip 21f and the first region 41b as viewed in a thickness direction of a substrate 17b. In FIG. 7, for ease of understanding, wire 24f connecting the semiconductor chip 21f and a semiconductor chip 22f and wire 24e connecting a semiconductor chip 21e and a semiconductor chip 22e are not illustrated. The semiconductor device of Embodiment 2 differs from that of Embodiment 1 in shapes of the first and second regions.

Referring to FIGS. 7 and 8, in the semiconductor device 11b of Embodiment 2, the semiconductor chip 21f is rectangular as viewed in the thickness direction of the substrate 17b. The first region 41b, arranged on the semiconductor chip 21f in contact with the semiconductor chip 21f, is rectangular as viewed in the thickness direction of the substrate 17b. It should be noted that the second region 42b, arranged on the first region 41b, is also rectangular as viewed in the thickness direction of the substrate 17b. As viewed in the thickness direction of the substrate 17b, the semiconductor chip 21f and the first region 41b have their centers O overlapping each other. A projection plane of the first region 41b has one side whose length is not more than twice the length of one side of the projection plane of the semiconductor chip 21f corresponding to the one side of the projection plane of the first region 41b. Specifically, the length of one side of the projection plane of the first region 41b is twice the length of one side of the projection plane of the semiconductor chip 21f corresponding to the one side of the projection plane of the first region 41b. That is, when the length of one side of the projection plane as the length in the X direction of the semiconductor chip 21f is L₁ and the length of one side of the projection plane as the length in the X direction of the first region 41b is S₁, then S₁=2×L₁. Further, when the length of one side of the projection plane as the length in the Y direction of the semiconductor chip 21f is L₂ and the length of one side of the projection plane as the length in the Y direction of the first region 41b is S₂, then S₂=2×L₂. It should be noted that when the semiconductor chip 21f has a square shape as viewed in the thickness direction of the substrate 17b, then L₁=L₂.

In such a semiconductor device 11b, it is possible to suppress the occurrence of partial discharge in the regions on the semiconductor chips 21a-21f and 22a-22f as well as in the surrounding regions. Accordingly, the above-described semiconductor device 11b is a semiconductor device that can be improved in reliability even more reliably.

In the above-described embodiment, the length of one side of the projection plane of the first region 41b may be not more than twice the length of one side of the projection plane of the semiconductor chip 21f corresponding to the one side of the projection plane of the first region 41b. That is, the first region 41b, and also the second region 42b, may be configured to hold the relationship of: S₁≤2×L₁. Further, the first region 41b, and also the second region 42b, may be configured to hold the relationship of: S₂≤2×L₂.

### Other Embodiments

In the above-described embodiments, the epoxy resin is used as the resin constituting the resin portion 40. However, not limited thereto, silicone gel or urethane resin may be used as the resin constituting the resin portion 40. In other words, the resin constituting the resin portion 40 may be silicone gel, epoxy resin, or urethane resin. Such resins have high insulating properties, leading to further improvement in reliability.

In the above-described embodiments, the second regions are located on a side on the first regions opposite from the side where the semiconductor chips are located, and the second regions are in contact with the first regions. However, not limited thereto, the second regions and the first regions may not contact each other. The second regions may be located on a side of the first regions opposite from the side where the semiconductor chips are located and may be spaced apart from the first regions.

It should be understood that the embodiments disclosed herein are illustrative and non-restrictive in every respect. The scope of the present disclosure is defined by the terms of the claims, rather than the description above, and is intended to include any modifications within the scope and meaning equivalent to the terms of the claims.

### REFERENCE SIGNS LIST

11a, 11b: semiconductor device; 12: heat dissipation plate; 12a, 12b: main surface; 13: frame body; 13a, 13b, 13c, 13d: wall portion; 14a, 14b: insulating plate; 15a, 15b, 15c, 15d, 15e, 15f, 15g: circuit board; 16a, 16b: circuit pattern; 17a, 17b: substrate; 18a, 18b, 18c, 18d: terminal; 19a, 19b, 19c, 19d: terminal; 20: case; 21a, 21b, 21c, 21d, 21e, 21f, 22a, 22b, 22c, 22d, 22e, 22f: semiconductor chip; 23a, 23b, 23c, 23d, 24a, 24b, 24c, 24d, 24e, 24f, 25a, 25b, 25c, 25d, 25e, 25f, 26a, 26b, 26c, 26d, 29a, 29b: wire; 27a, 27b, 27c, 27d: inner wall surface; 30: space; 31a, 31b: first main surface; 40: resin portion; 41a, 41b: first region; 42a, 42b: second region; 43: air bubble; 44: discharge portion; 45: hole; D₁, D₂, Dₐ: thickness; D₃: height, L₁, L₂, S₁, S₂: length, and O: center.

1. A semiconductor device comprising:
a substrate including a first main surface and having a circuit pattern;
a semiconductor chip disposed on the circuit pattern;
a frame body extending in a direction intersecting the first main surface and surrounding an outer periphery of the substrate; and
a resin portion arranged in a space surrounded by the frame body and covering the substrate and the semiconductor chip;
the resin portion including
a first region located on the semiconductor chip in contact with the semiconductor chip, and
a second region located on a side of the first region opposite from a side on which the semiconductor chip is located, the second region having a same volume as the first region and having a projection plane projected in a same shape as the first region as viewed in a thickness direction of the substrate,
the amount of air bubbles contained in the resin portion arranged in the first region being smaller than the amount of air bubbles contained in the resin portion arranged in the second region.

2. The semiconductor device according to claim 1, further comprising a conductive member connected to the semiconductor chip in the first region, wherein
the first region and the second region each have a thickness not less than a height of the conductive member and not more than 50% of an entire thickness of the resin portion.

3. The semiconductor device according to claim 1, wherein the semiconductor chip is a wide bandgap semiconductor.

4. The semiconductor device according to claim 1, wherein a resin constituting the resin portion is silicone gel, epoxy resin, or urethane resin.

5. The semiconductor device according to claim 1, wherein as viewed in the thickness direction of the substrate, the first region has a projection plane projected in a same shape as the semiconductor chip.

6. The semiconductor device according to claim 1, wherein as viewed in the thickness direction of the substrate,
the semiconductor chip and the first region each have a rectangular shape,
a projection plane of the semiconductor chip and a projection plane of the first region have centers overlapping each other, and
one side of the projection plane of the first region has a length not more than twice a length of one side of the projection plane of the semiconductor chip corresponding to the one side of the projection plane of the first region.

7. A method of producing a semiconductor device,
the semiconductor device including
a substrate including a first main surface and having a circuit pattern,
a semiconductor chip disposed on the circuit pattern,
a frame body extending in a direction intersecting the first main surface and surrounding an outer periphery of the substrate, and
a resin portion arranged in a space surrounded by the frame body and covering the substrate and the semiconductor chip,
the method comprising the steps of:
arranging the frame body to surround the substrate;
following the arranging step, injecting a resin constituting the resin portion into the space surrounded by the frame body at a first speed; and
following the step of injecting the resin at the first speed, injecting the resin constituting the resin portion into the space surrounded by the frame body at a second speed faster than the first speed.

8. A method of producing a semiconductor device,
the semiconductor device including
a substrate including a first main surface and having a circuit pattern,
a semiconductor chip disposed on the circuit pattern,
a frame body extending in a direction intersecting the first main surface and surrounding an outer periphery of the substrate, and
a resin portion arranged in a space surrounded by the frame body and covering the substrate and the semiconductor chip,
the method comprising the steps of:
arranging the frame body to surround the substrate;
following the arranging step, injecting a resin constituting the resin portion, the resin being at a first temperature, into the space surrounded by the frame body; and
following the step of injecting the resin at the first temperature, injecting the resin constituting the resin portion, the resin being at a second temperature lower than the first temperature, into the space surrounded by the frame body.

9. The semiconductor device according to claim 2, wherein the semiconductor chip is a wide bandgap semiconductor.

10. The semiconductor device according to claim 2, wherein a resin constituting the resin portion is silicone gel, epoxy resin, or urethane resin.

11. The semiconductor device according to claim 3, wherein a resin constituting the resin portion is silicone gel, epoxy resin, or urethane resin.

12. The semiconductor device according to claim 2, wherein as viewed in the thickness direction of the substrate, the first region has a projection plane projected in a same shape as the semiconductor chip.

13. The semiconductor device according to claim 3, wherein as viewed in the thickness direction of the substrate, the first region has a projection plane projected in a same shape as the semiconductor chip.

14. The semiconductor device according to claim 4, wherein as viewed in the thickness direction of the substrate, the first region has a projection plane projected in a same shape as the semiconductor chip.

15. The semiconductor device according to claim 2, wherein as viewed in the thickness direction of the substrate,
the semiconductor chip and the first region each have a rectangular shape,
a projection plane of the semiconductor chip and a projection plane of the first region have centers overlapping each other, and
one side of the projection plane of the first region has a length not more than twice a length of one side of the projection plane of the semiconductor chip corresponding to the one side of the projection plane of the first region.

16. The semiconductor device according to claim 3, wherein as viewed in the thickness direction of the substrate,
the semiconductor chip and the first region each have a rectangular shape,
a projection plane of the semiconductor chip and a projection plane of the first region have centers overlapping each other, and
one side of the projection plane of the first region has a length not more than twice a length of one side of the projection plane of the semiconductor chip corresponding to the one side of the projection plane of the first region.

17. The semiconductor device according to claim 4, wherein as viewed in the thickness direction of the substrate,
the semiconductor chip and the first region each have a rectangular shape,
a projection plane of the semiconductor chip and a projection plane of the first region have centers overlapping each other, and
one side of the projection plane of the first region has a length not more than twice a length of one side of the projection plane of the semiconductor chip corresponding to the one side of the projection plane of the first region.

18. The semiconductor device according to claim 9, wherein a resin constituting the resin portion is silicone gel, epoxy resin, or urethane resin.

19. The semiconductor device according to claim 18, wherein as viewed in the thickness direction of the substrate, the first region has a projection plane projected in a same shape as the semiconductor chip.

20. The semiconductor device according to claim 18, wherein as viewed in the thickness direction of the substrate,
the semiconductor chip and the first region each have a rectangular shape,
a projection plane of the semiconductor chip and a projection plane of the first region have centers overlapping each other, and
one side of the projection plane of the first region has a length not more than twice a length of one side of the projection plane of the semiconductor chip corresponding to the one side of the projection plane of the first region.
